(19) United States
(12) Patent Application Publication
(10) Pub. No.: US 2015/0035608 A1
(43) Pub. Date: Feb. 5, 2015

(54) DISTORTION COMPENSATING APPARATUS AND DISTORTION COMPENSATION METHOD

(71) Applicant: FUJITSU LIMITED, Kawasaki-shi (JP)

(72) Inventors: Takumi MIYASHITA, Inagi (JP); Takeshi TAKANO, Yokohama (JP)

(21) Appl. No.: 14/447,255

(22) Filed: Jul. 30, 2014

(30) Foreign Application Priority Data
Aug. 2, 2013 (JP) 2013-161100

(51) Int. Cl. H03F 1/02; H03F 1/32

(52) U.S. Cl. CPC H03F 1/0233; H03F 1/3205; H03F 2201/3215
USPC 330/297

(57) ABSTRACT

A distortion compensating apparatus includes: a memory; and a processor coupled to the memory and configured to: calculate a transient response of a power source circuit, in accordance with an estimated value of a current to be consumed by an amplifier based on a signal to be amplified by the amplifier, and in accordance with an objective supply voltage, based on the signal, of a voltage to be supplied to the amplifier from the power source circuit, and correct the signal to be input to the amplifier based on a difference caused by the transient response from the objective supply voltage.

### CROSS-REFERENCE TO RELATED APPLICATION

This application is based upon and claims the benefit of priority of the prior Japanese Patent Application No. 2013-161100, filed on Aug. 2, 2013, the entire contents of which are incorporated herein by reference.

### FIELD

The embodiments discussed herein are related to a distortion compensating apparatus and a distortion compensation method.

### BACKGROUND

Traditionally, as a method for improving an efficiency of amplification by an amplifier of a wireless transmitter, a technique for controlling a supply voltage based on a signal level is known. For example, a configuration for controlling, based on an average of input power levels, a supply voltage to be supplied to a power amplifier is known (refer to, for example, Japanese Laid-open Patent Publication No. 2002-314345).

### SUMMARY

According to an aspect of the invention, a distortion compensating apparatus includes: a memory; and a processor coupled to the memory and configured to: calculate a transient response of a power source circuit, in accordance with an estimated value of a current to be consumed by an amplifier based on a signal to be amplified by the amplifier, and in accordance with an objective supply voltage, based on the signal, of a voltage to be supplied to the amplifier from the power source circuit, and correct the signal to be input to the amplifier based on a difference caused by the transient response from the objective supply voltage.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a diagram illustrating an example of a distortion compensating apparatus according to a first embodiment;

FIG. 1B is a diagram illustrating an example of the flows of signals in the distortion compensating apparatus illustrated in FIG. 1A;

FIG. 2A is a diagram illustrating a first example of a configuration of an amplifying device according to a second embodiment;

FIG. 2B is a diagram illustrating an example of the flows of signals in the amplifying device illustrated in FIG. 2A;

FIG. 3A is a diagram illustrating a second example of the configuration of the amplifying device according to the second embodiment;

FIG. 3B is a diagram illustrating an example of the flows of signals in the amplifying device illustrated in FIG. 3A;

FIG. 4A is a diagram illustrating an example of a configuration for providing an estimated value of a current to be consumed and an objective supply voltage;

FIG. 4B is a diagram illustrating an example of the flows of signals in the configuration illustrated in FIG. 4A;

FIG. 5A is a diagram illustrating a first example of a configuration of a transient response calculator and a configuration of an estimated current value calculator;

FIG. 5B is a diagram illustrating an example of the flows of signals in the example, illustrated in FIG. 5A, of the configuration of the transient response calculator and the configuration of the estimated current value calculator;

FIG. 6A is a diagram illustrating a second example of the configuration of the transient response calculator and the configuration of the estimated current value calculator;

FIG. 6B is a diagram illustrating an example of the flows of signals in the example, illustrated in FIG. 6A, of the configuration of the transient response calculator and the configuration of the estimated current value calculator;

FIG. 7A is a diagram illustrating a third example of the configuration of the transient response calculator and the configuration of the estimated current value calculator;

FIG. 7B is a diagram illustrating an example of the flows of signals in the example, illustrated in FIG. 7A, of the configuration of the transient response calculator and the configuration of the estimated current value calculator;

FIG. 8A is a diagram illustrating an example of a configuration of a power source supplier and a configuration of a modulator;

FIG. 8B is a diagram illustrating an example of the flows of signals in the example, illustrated in FIG. 8A, of the configuration of the power source supplier and the configuration of the modulator;

FIG. 9 is a diagram illustrating an example of a control signal and the waveform of a voltage supplied;

FIG. 10A is a diagram illustrating an output spectrum of a power amplifier when voltage supply control is stopped as a reference; and

FIG. 10B is a diagram illustrating an output spectrum of the power amplifier when voltage supply control is executed.

### DESCRIPTION OF EMBODIMENTS

Hereinafter, embodiments of a distortion compensating apparatus disclosed herein and a distortion compensation method disclosed herein are described in detail with reference to the accompanying drawings.

While inventing the present embodiments, observations were made regarding a related art. Such observations include the following, for example.

For the aforementioned technique of the related art, it may be difficult to improve the amplification efficiency due to a limit on a speed at which a supply voltage is controlled when a frequency band of a signal to be amplified is wide.

According to an aspect, an object of the disclosure is to provide a distortion compensating apparatus and a distortion compensation method that improve an amplification efficiency.

### First Embodiment

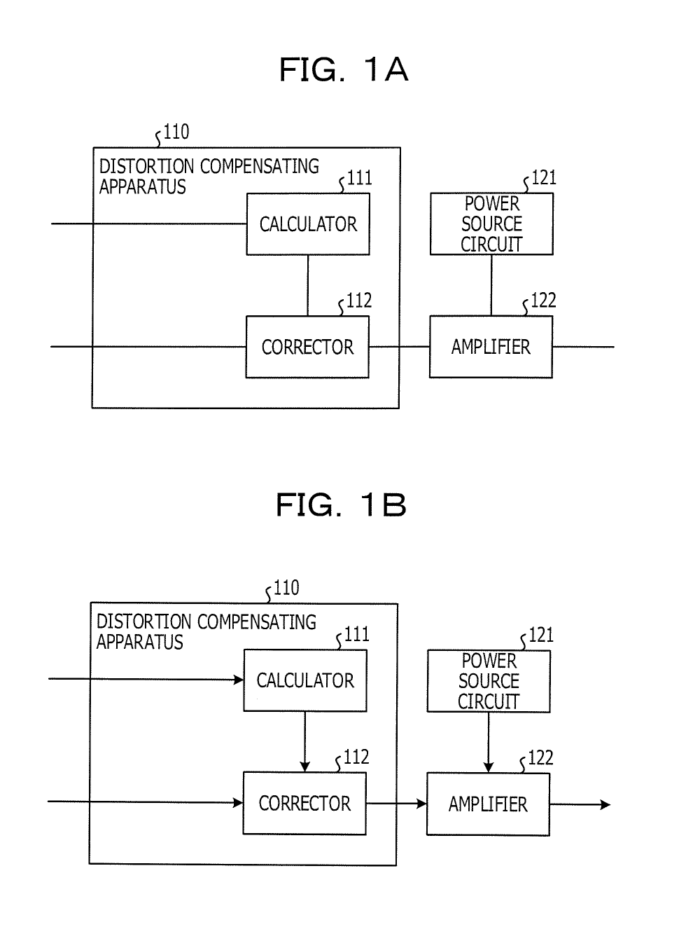

FIG. 1A is a diagram illustrating an example of a distortion compensating apparatus according to a first embodiment. FIG. 1B is a diagram illustrating an example of the flows of signals in the distortion compensating apparatus illustrated in FIG. 1A. As illustrated in FIGS. 1A and 1B, the distortion compensating apparatus 110 according to the first embodiment includes a calculator 111 and a corrector 112. The distortion compensating apparatus 110 corrects a signal to be amplified by an amplifier 122 and thereby compensates for a distortion of the signal amplified by the amplifier 122. A power source circuit 121 is a circuit for controlling, based on the input signal, a voltage to be supplied to the amplifier 122.

An estimated value of a current to be consumed by the amplifier 122 based on the signal to be amplified by the amplifier 122 and an objective supply voltage, based on the signal to be amplified, of a voltage to be supplied from the power source circuit 121 to the amplifier 122 are input to the calculator 111. The calculator 111 calculates a transient response of the power source circuit 121 based on the input estimated value of the current to be consumed by the amplifier 122 and the input objective supply voltage.

Then, the calculator 111 informs the corrector 112 of the difference between the calculated transient response and the input objective supply voltage. The corrector 112 corrects the signal to be input to the amplifier 122 based on the difference, informed by the calculator 111, between the transient response and the objective supply voltage. Thus, the distortion compensating apparatus 110 may compensate for a distortion, caused by a power supply variation, of the signal amplified by the amplifier 122.

In this manner, the distortion compensating apparatus 110 may calculate the transient response of the power source circuit 121 from the estimated current to be consumed by the amplifier 122 based on the signal to be amplified and the objective supply voltage of a voltage to be supplied to the amplifier 122 based on the signal to be amplified. Then, the distortion compensating apparatus 110 may correct the signal to be amplified based on an error of the calculated transient response with respect to the objective supply voltage.

Thus, even if a frequency band of the signal to be amplified is wide, the distortion compensating apparatus 110 may compensate for a distortion, caused by a power source variation, of the signal and improve an efficiency of amplification by the amplifier 122.

The distortion compensating apparatus 110 transmits, to the power source circuit 121, a differentiated signal representing the difference between the transient response calculated by the calculator 111 and the objective supply voltage. The power source circuit 121 controls, based on the differentiated signal received from the distortion compensating apparatus 110, the voltage to be supplied to the amplifier 122. Thus, the distortion compensating apparatus 110 may control, based on power to be amplified, the voltage to be supplied to the amplifier 122 and improve the efficiency of the amplification by the amplifier 122.

The calculator 111 may calculate the transient response based on an estimated value based on the difference between the transient response, calculated by the calculator 111, to a current flowing in the power source circuit 121 and the objective supply voltage of the voltage to be supplied. Thus, the calculator 111 may correct a ripple caused by an error occurred in the power source circuit 121 (switching regulator) and calculate the transient response with high accuracy. The distortion compensating apparatus 110 may compensate for a distortion, caused by a power source variation, of the signal with high accuracy and improve the efficiency of the amplification by the amplifier 122.

For example, the calculator 111 may quantize the differentiated signal representing the difference between the transient response calculated by the calculator 111 and the objective supply voltage and calculate, based on the quantized differentiated signal, an estimated value of the current flowing in the power source circuit 121. The distortion compensating apparatus 110 may transmit the quantized differentiated signal to the power source circuit 121 in order to transmit the differentiated signal to the power source circuit 121.

For example, the calculator 111 may calculate the transient response using a digital filter. In this case, the digital filter has, in an input part, a nonlinear gain corresponding to the transient response of the power source circuit 121, while the transient response varies depending on impedance of the amplifier 122. The nonlinear gain may be represented by a polynomial or a lookup table.

The calculator 111 and the corrector 112 may be achieved by a digital processing circuit such as a digital signal processor (DSP) that executes a program stored in a memory, for example.

### Second Embodiment

### First Example of Configuration of Amplifying Device According to Second Embodiment

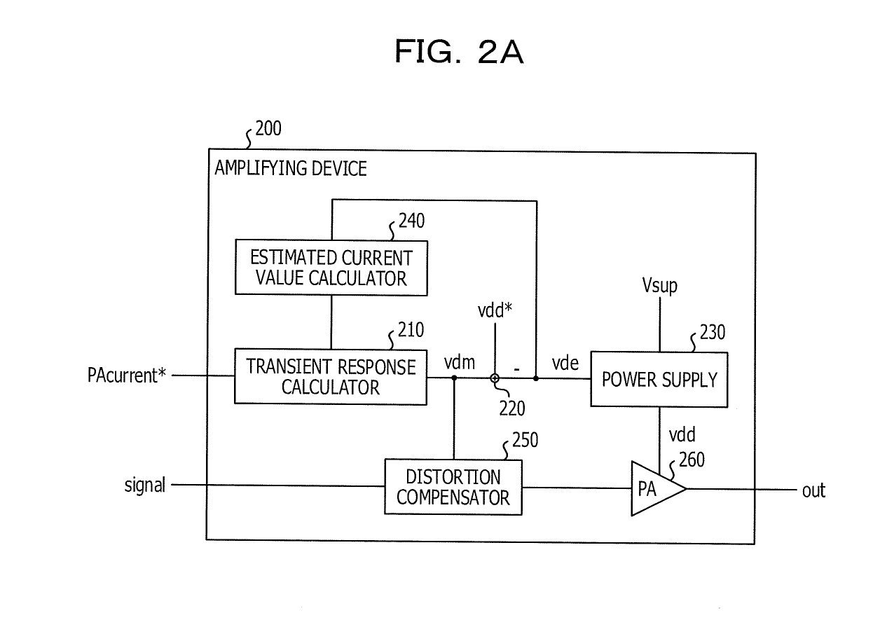

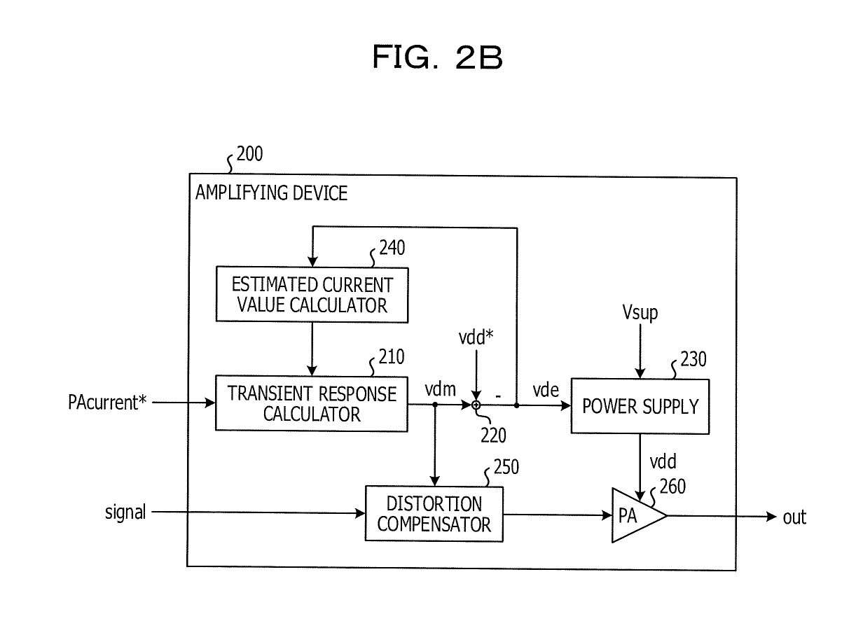

FIG. 2A is a diagram illustrating a first example of a configuration of an amplifying device according to a second embodiment. As illustrated in FIGS. 2A and 2B, the amplifying device 200 according to the second embodiment is configured to amplify a signal (signal) input to the amplifying device 200 and output the amplified signal (out). For example, the amplifying device 200 is installed in a wireless transmitter and amplifies a high-frequency signal to be transmitted by the wireless transmitter.

The amplifying device 200 includes a transient response calculator 210 (transient response*), a subtractor 220, and a power supply 230. The amplifying device 200 further includes an estimated current value calculator 240 (supply current*), a distortion compensator 250 (compensation), a power amplifier (PA) 260.

The calculator 111 illustrated in FIGS. 1A and 1B may be achieved by the transient response calculator 210, the subtractor 220, and the estimated current value calculator 240, for example. The corrector 112 illustrated in FIGS. 1A and 1B may be achieved by the distortion compensator 250, for example. The power source circuit 121 illustrated in FIGS. 1A and 1B may be achieved by the power supply 230, for example. The amplifier 122 illustrated in FIGS. 1A and 1B may be achieved by the power amplifier 260, for example.

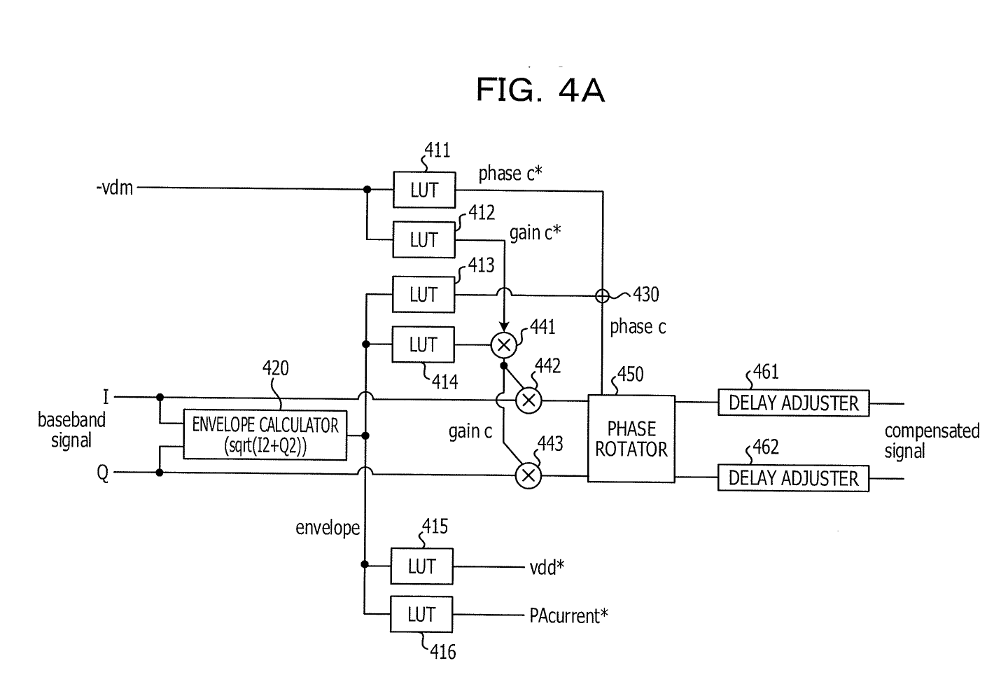

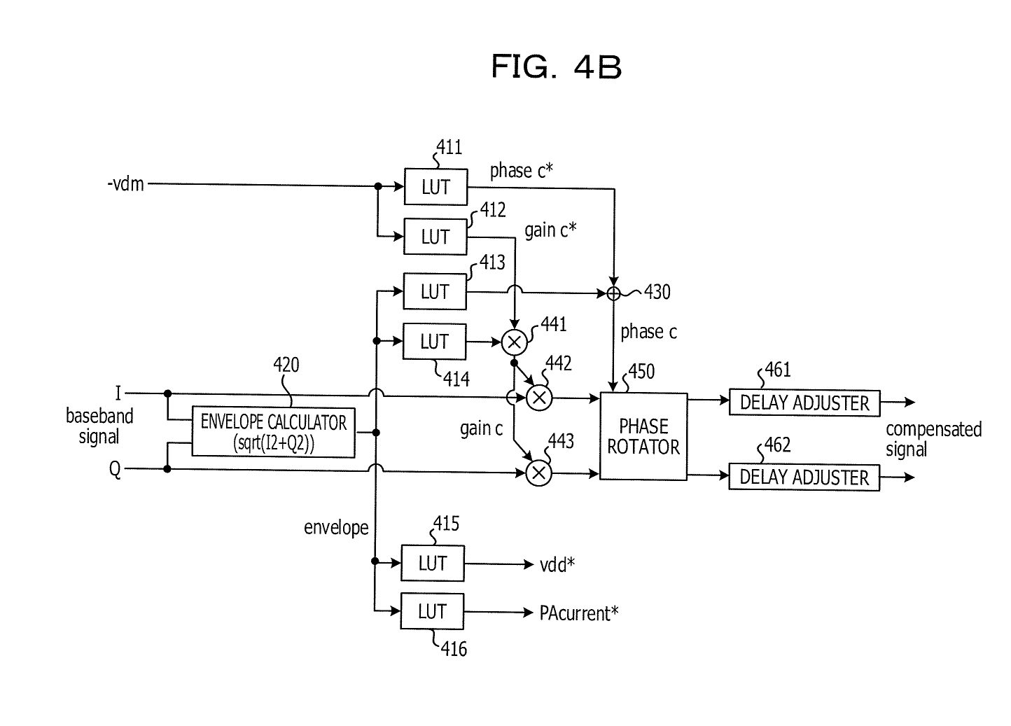

A standard consumption current value (PAcurrent*) based on the signal (signal) to be transmitted is input to the transient response calculator 210. The standard consumption current value is a standard value of a current to be consumed by the power amplifier 260. For example, the transient response calculator 210 acquires the standard consumption current value from a signal generating circuit that generates the signal to be transmitted. The signal generating circuit calculates, based on a characteristic of the power amplifier 260, the standard consumption current value corresponding to the generated signal to be transmitted and outputs the calculated standard consumption current value to the transient response calculator 210 (refer, for example, to FIGS. 4A and 4B).

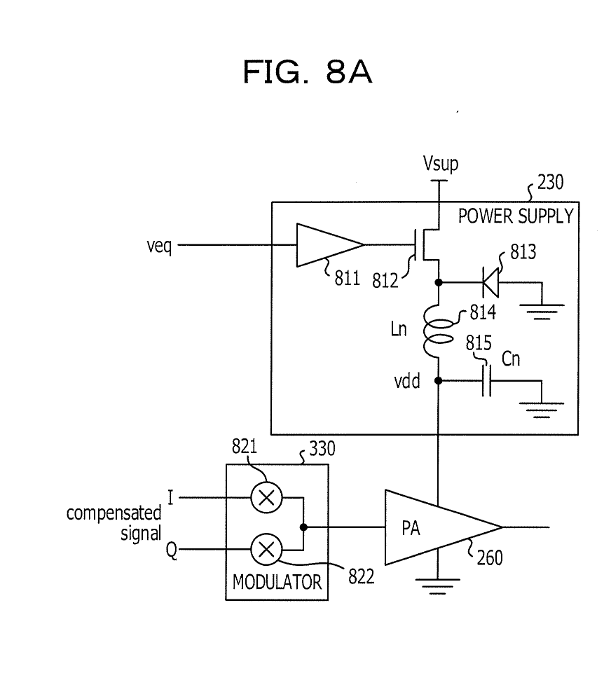

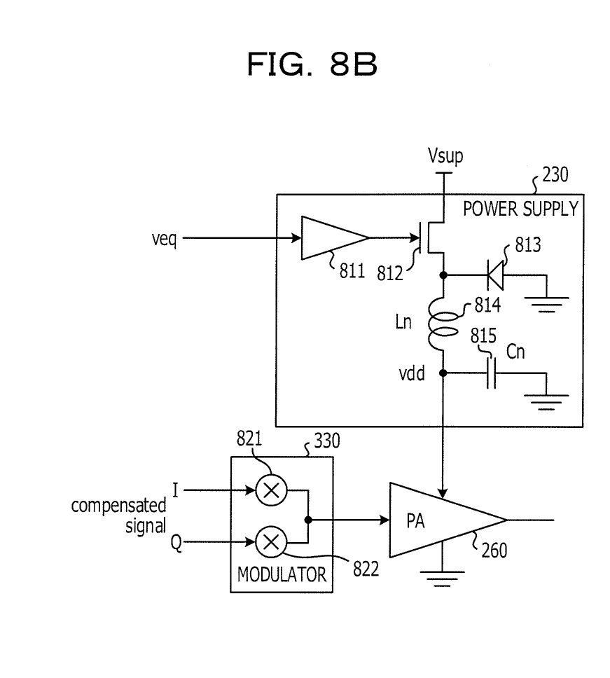

The transient response calculator 210 calculates the transient response of the power source circuit based on the input standard consumption current value. The transient response calculator 210 may calculate the transient response of the power source circuit based on the input standard consumption current value and an estimated current value output from the estimated current value calculator 240. The transient response of the power source circuit is a transient response to a supply voltage to be output to the power amplifier 260 from an LC circuit (refer, for example, to FIGS. 8A and 8B) included in the power supply 230, for example.

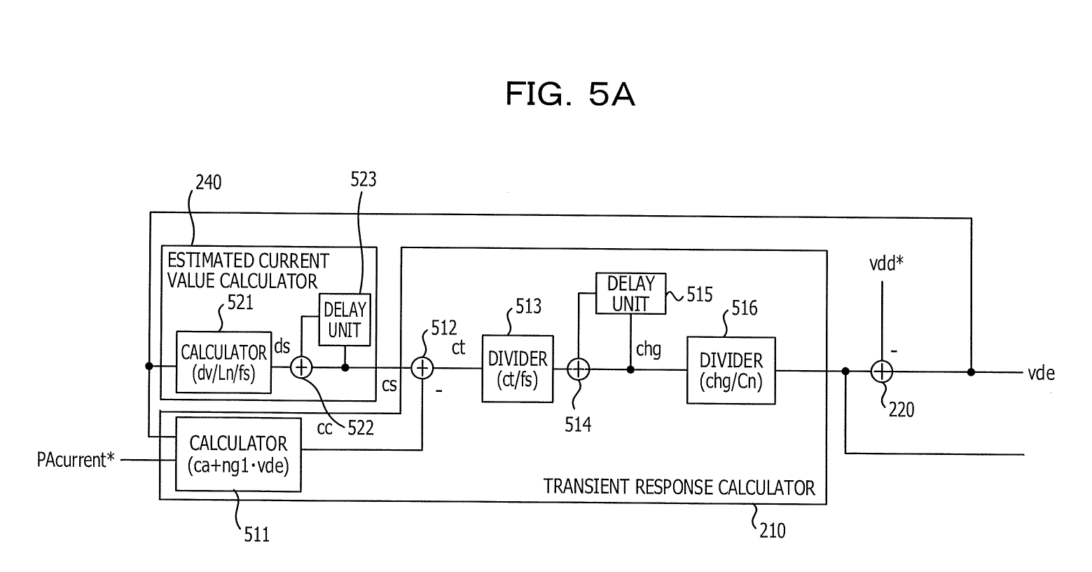

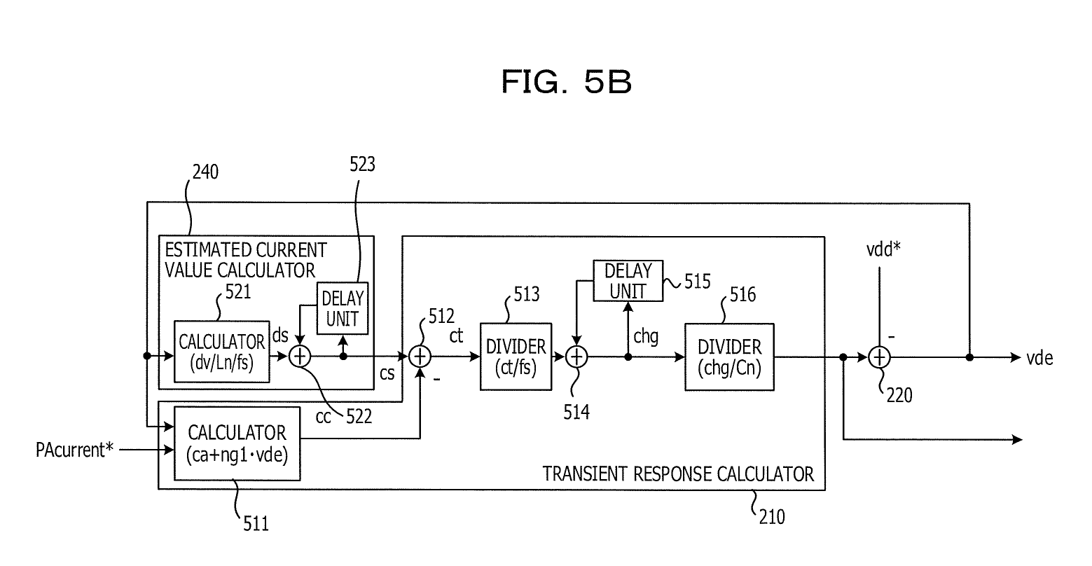

The result of the calculation by the transient response calculator 210 represents an estimated value (estimated supply voltage) of the supply voltage to be supplied from the power supply 230 to the power amplifier 260. The transient response calculator 210 outputs the estimated supply voltage (vdm) to the subtractor 220 and the distortion compensator 250. A configuration of the transient response calculator 210 is described later (refer, for example, to FIGS. 5A to 7B).

The subtractor 220 calculates the difference between the estimated supply voltage output from the transient response calculator 210 and an objective supply voltage (vdd*). Thus, the subtractor 220 may calculate an error of the estimated value of the supply voltage to be supplied from the power supply 230 to the power amplifier 260 with respect to the objective supply voltage. The objective supply voltage is an objective value of the supply voltage based on the signal to be transmitted. The objective supply voltage is set based on an envelope signal for the signal to be transmitted, for example (refer, for example, to FIGS. 4A and 4B). The substractor 220 outputs the result of the calculation as a differentiated signal (vde) to the power supply 230 and the estimated current value calculator 240.

The power supply 230 is a power source circuit for supplying power to the power amplifier 260 using input power (Vsup). In addition, the power supply 230 controls the power to be supplied to the power amplifier 260 so as to ensure that the difference represented by the differentiated signal output from the subtractor 220 is reduced. A configuration of the power supply 230 is described later (refer, for example, to FIGS. 8A and 8B).

The estimated current value calculator 240 calculates, based on the differentiated signal output from the subtractor 220, an estimated value (supply current*) of a current flowing in the power source circuit. The estimated value, calculated by the estimated current value calculator 240, of the current flowing in the power source circuit is an estimated value of a current flowing in the LC circuit (refer, for example, to FIGS. 8A and 8B) included in the power supply 230, for example. The estimated current value calculator 240 outputs the calculated estimated current value to the transient response calculator 210. A configuration of the estimated current value calculator 240 is described later (refer, for example, to FIGS. 5A to 7B).

The distortion compensator 250 compensates for, based on the estimated supply voltage output from the transient response calculator 210, a distortion of the signal (signal) to be transmitted. For example, the distortion compensator 250 compensates for the distortion by providing, to the signal to be transmitted, an inverse characteristic of a distortion, caused by a delay of voltage supply control to be executed by the power supply 230, of the signal to be output from the power amplifier 260. The distortion compensator 250 may compensate for the distortion using any of various methods.

For example, signals of I and Q channels that are to be transmitted are input to the distortion compensator 250, and the distortion compensator 250 compensates for distortions of the input signals to be transmitted. The distortion compensator 250 outputs the signals subjected to the distortion compensation to the power amplifier 260.

The power amplifier 260 uses the supply voltage supplied from the power supply 230 and thereby amplifies power of the signals output from the distortion compensator 250 and to be transmitted. Then, the power amplifier 260 outputs the signals (out) with the power amplified.

The transient response calculator 210, the subtractor 220, and the estimated current value calculator 240 may be achieved by a digital processing circuit such as a DSP that executes a program stored in a memory, for example.

### Second Example of Configuration of Amplifying Device According to Second Embodiment

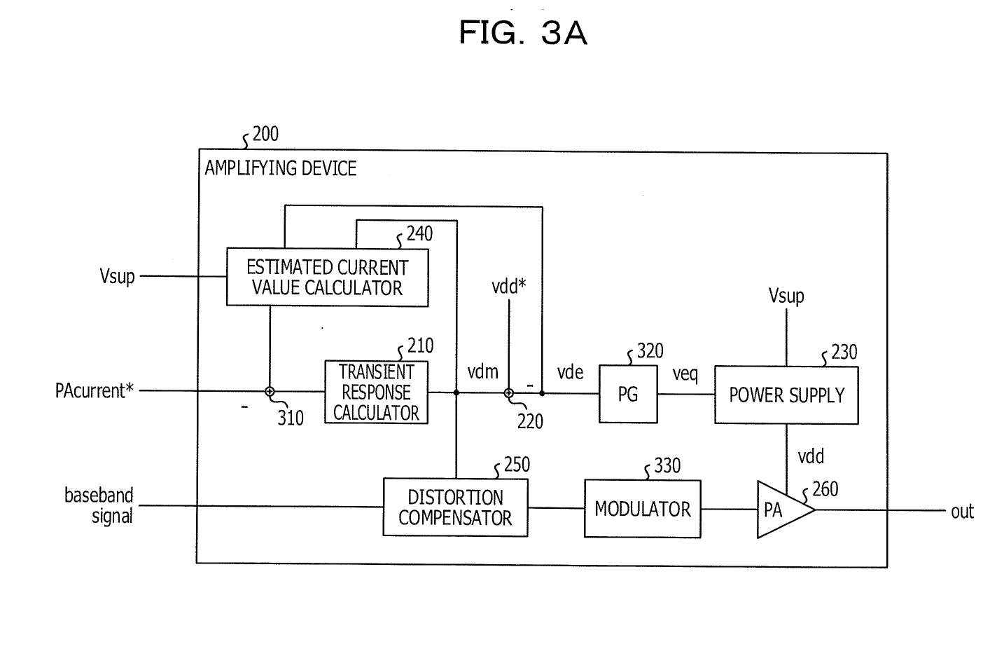

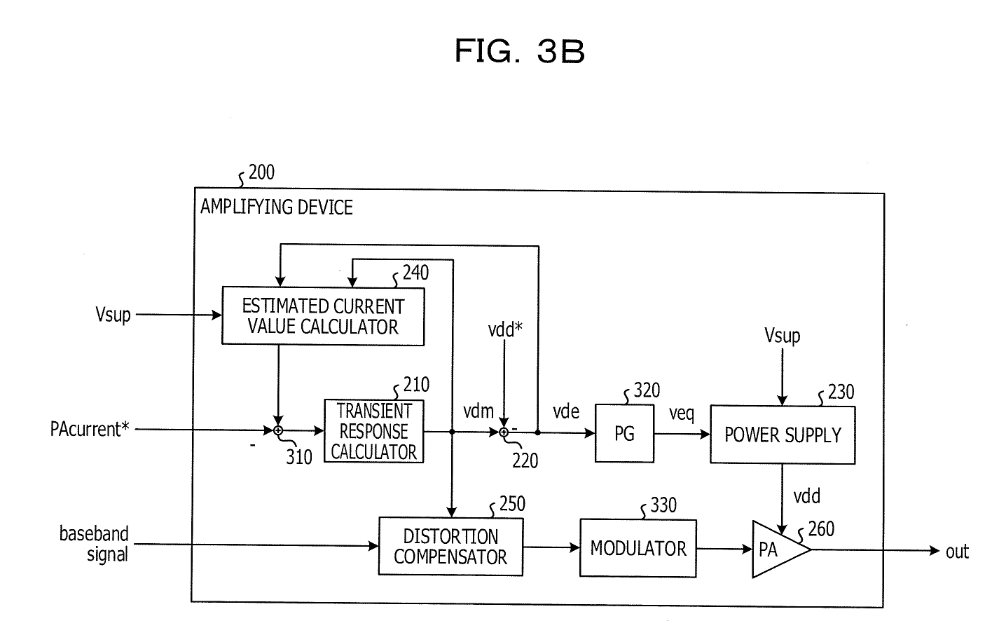

FIG. 3A is a diagram illustrating a second example of the configuration of the amplifying device according to the second embodiment. FIG. 3B is a diagram illustrating an example of the flows of signals in the amplifying device illustrated in FIG. 3A. Parts that are illustrated in FIGS. 3A and 3B and are the same as the parts illustrated in FIGS. 2A and 2B are represented by the same reference numbers as those illustrated in FIGS. 2A and 2B, and a description thereof is omitted.

The amplifying device 200 illustrated in FIGS. 3A and 3B includes a subtractor 310, the transient response calculator 210 (vdm), the subtractor 220, a pulse generator (PG) 320, and the power supply 230. The amplifying device 200 further includes the estimated current value calculator 240, the distortion compensator 250, a modulator 330, and the power amplifier 260.

The subtractor 310 calculates the difference between the input standard consumption current value and an estimated current value output from the estimated current value calculator 240. Then, the subtractor 310 outputs the result of the calculation to the transient response calculator 210.

The transient response calculator 210 calculates the transient response of the power source circuit based on the calculation result output from the subtractor 310. The transient response calculator 210 may be achieved by a digital filter such as an infinite impulse response (IIR) filter, for example. The transient response calculator 210 outputs the result of the calculation to the subtractor 220, the estimated current value calculator 240, and the distortion compensator 250.

The subtractor 220 outputs a differentiated signal representing the difference to the pulse generator 320 and the estimated current value calculator 240. The pulse generator 320 executes pulse width modulation based on the differentiated signal output from the subtractor 220. Then, the pulse generator 320 outputs a pulse signal (veq) obtained by the pulse width modulation to the power supply 230.

The power supply 230 is a switching power supply configured to output the supply voltage to the power amplifier 260 based on the pulse signal output from the pulse generator 320 (refer, for example, to FIGS. 8A and 8B).

The estimated current value calculator 240 calculates, based on the result, output from the transient response calculator 210, of calculating the transient response and the differentiated signal output from the subtractor 220, an estimated value of the current flowing in the power source circuit. For example, the estimated current value calculator 240 calculates the estimated current value by estimating, based on the differentiated signal output from the subtractor 220, a current flowing in an inductor of a power source filter through a switching element of the power supply 230. The estimated current value calculator 240 may use the power Vsup to calculate the estimated value of the current flowing in the power source circuit.

A baseband signal (baseband signal) to be transmitted is input to the distortion compensator 250. The distortion compensator 250 compensates for a distortion of the input baseband signal to be transmitted. Then, the distortion compensator 250 outputs, to the modulator 330, the signal subjected to the distortion compensation and to be transmitted.

The modulator 330 modulates the signal output from the distortion compensator 250 and to be transmitted. Then, the modulator 330 outputs, to the power amplifier 260, the signal modulated and to be transmitted. The power amplifier 260 amplifies power of the signal output from the modulator 330 and to be transmitted.

### Configuration for Providing Estimated Value of Current to be Consumed and Objective Supply Voltage

FIG. 4A is a diagram illustrating an example of a configuration for providing an estimated value of a current to be consumed and an objective supply voltage. FIG. 4B is a diagram illustrating an example of the flows of signals in the configuration, illustrated in FIG. 4A, for providing an estimated value of a current to be consumed and an objective supply voltage.

The amplifying device 200 includes lookup tables (LUTs) 411 to 416 and an envelope calculator 420 on the upstream side of the configuration illustrated in FIGS. 3A and 3B. The amplifying device 200 further includes an adder 430, multipliers 441 to 443, a phase rotator 450, and delay adjusters 461 and 462.

The lookup tables 411 to 416 are generated in advance based on a characteristic of the power amplifier 260. An estimated error value (−vdm) with respect to the objective supply voltage of a voltage to be supplied to the power amplifier 260 from the power supply 230 is input to the lookup tables 411 and 412. The lookup table 411 stores information of an association of the estimated error value of the supply voltage with a phase correction amount based on the supply voltage for baseband signals to be transmitted. The lookup table 411 outputs, to the adder 430, the phase correction amount (phase c*) associated with the input estimated error value of the supply voltage.

The lookup table 412 stores information of an association of the estimated error value of the supply voltage with a gain correction amount based on the supply voltage for the baseband signals to be transmitted. The lookup table 412 outputs, to the multiplier 441, the gain correction amount (gain c*) associated with the input estimated error value of the supply voltage.

The baseband signal I (baseband signal) of the I channel is input to the envelope calculator 420 and the multiplier 442. The baseband signal Q (baseband signal) of the Q channel is input to the envelope calculator 420 and the multiplier 443.

The envelope calculator 420 calculates sqrt(I²+Q²) based on the input signals I and Q of the I and Q channels and thereby obtains an envelope signal (envelope) for the signals to be transmitted. The envelope calculator 420 outputs the calculated envelope signal to the lookup tables 413 to 416.

The lookup table 413 stores information of an association of the envelope signal with a distorted signal. The lookup table 413 outputs, to the adder 430, the distorted signal associated with the envelope signal output from the envelope calculator 420.

The lookup table 414 stores the information of the association of the envelop signal with the distorted signal. The lookup table 414 outputs, to the multiplier 441, the distorted signal associated with the envelope signal output from the envelope calculator 420.

The adder 430 adds the phase correction amount output from the lookup table 411 to the distorted signal output from the lookup table 413. The adder 430 outputs a result of the addition as a phase correction signal (phase c) to the phase rotator 450.

The multiplier 441 multiplies the gain correction amount output from the lookup table 412 by the distorted signal output from the lookup table 414. Then, the multiplier 441 outputs a result of the multiplication as a gain correction amount (gain c) to the multipliers 442 and 443.

The multiplier 442 corrects the amplitude of the input signal I of the I channel by multiplying the signal I of the I channel by the gain correction signal output from the multiplier 441. Then, the multiplier 442 outputs the signal I (of the I channel) with the amplitude corrected to the phase rotator 450.

The multiplier 443 corrects the amplitude of the input signal Q of the Q channel by multiplying the signal Q of the Q channel by the gain correction signal output from the multiplier 441. Then, the multiplier 443 outputs the signal Q (of the Q channel) with the amplitude corrected to the phase rotator 450.

The phase rotator 450 corrects the phases of the signals of the I and Q channels output from the multipliers 442 and 443 by rotating the phases of the I and Q channel signals based on the phase correction signal output from the adder 430. Then, the phase rotator 450 outputs the I channel signal with the phase corrected to the delay adjuster 461. The phase rotator 450 outputs the Q channel signal with the phase corrected to the delay adjuster 462.

The delay adjusters 461 and 462 are configured to adjust delay differences between the signals to be input to the power amplifier 260 and the voltage to be supplied to the power amplifier 260 from the power supply 230. The delay adjuster 461 delays the I channel signal output from the phase rotator 450 in order to match the timing of supplying the supply voltage with the timing of inputting the I channel signal. The delay adjuster 462 delays the Q channel signal output from the phase rotator 450 in order to match the timing of supplying the supply voltage with the timing of inputting the Q channel signal. The delay adjusters 461 and 462 output the delayed I and Q channel signals (compensated signals) to the distortion compensator 250 (refer, for example, to FIGS. 2A to 3B), for example.

The lookup table 415 stores information of an association of the envelope signal with the objective supply voltage. The lookup table 415 outputs, to the subtractor 220 (refer, for example, to FIGS. 2A to 3B), the objective supply voltage (vdd*) associated with the envelope signal output from the envelope calculator 420.

The lookup table 416 stores information of an association of the envelope signal with the estimated value of the current to be consumed. The lookup table 416 outputs the estimated value (PAcurrent*), associated with the envelope signal output from the envelope calculator 420, of the current to be consumed to the transient response calculator 210 (refer, for example, to FIGS. 2A to 3B).

### Example of Configurations of Transient Response Calculator and Estimated Current Value Calculator

FIG. 5A is a diagram illustrating a first example of a configuration of the transient response calculator and a configuration of the estimated current value calculator. FIG. 5B is a diagram illustrating an example of the flows of signals in the example, illustrated in FIG. 5A, of the configuration of the transient response calculator and the configuration of the estimated current value calculator. As illustrated in FIGS. 5A and 5B, the transient response calculator 210 includes a calculator 511, a subtractor 512, a divider 513, an adder 514, a delay unit 515, and a divider 516, for example.

The calculator 511 calculates a value of (ca+ng1·vde), where ca represents the standard value (PAcurrent*), input to the transient response calculator 210, of the current to be consumed, ng1 represents equivalent impedance of a power terminal of the power amplifier 260 and may be represented by a polynomial of ca, and vde represents the differentiated signal (vde) output from the subtractor 220. The calculator 511 outputs the result (cc) of the calculation to the subtractor 512.

The subtractor 512 calculates the difference between the calculation result (cc) output from the calculator 511 and an estimated current value (cs) output from the estimated current value calculator 240. Thus, the subtractor 512 may calculate a current flowing into capacitance of the LC circuit included in the power supply 230. The subtractor 512 outputs the result (ct) of the calculation to the divider 513. The divider 513 divides the calculation result (ct) output from the subtractor 512 by a sampling frequency fs. The divider 513 outputs a result of the division to the adder 514.

The adder 514 and the delay unit 515 form a digital filter with a nonlinear gain. The adder 514 adds the division result output from the divider 513 to a signal output from the delay unit 515 and thereby calculates the amount (chg) of electric charge held by the capacitance of the LC circuit included in the power supply 230. The adder 514 outputs a result of the addition to the delay unit 515 and the divider 516. The delay unit 515 delays the addition result output from the adder 514 for a predetermined time and outputs the addition result to the adder 514.

The divider 516 divides the addition result output from the delay unit 515 by Cn representing the capacitance (for example, a capacitor 815 illustrated in FIGS. 8A and 8B) of the LC circuit included in the power supply 230. Thus, the divider 516 may calculate the estimated supply voltage (vdm). The divider 516 outputs the calculated estimated supply voltage to the subtractor 220 and the like.

Specifically, the transient response calculator 210 may calculate the estimated supply voltage (vdm) according to the following Equation (1), for example.

$$vdm = \int \frac{chg}{Cn} \cdot dt \qquad ( 1 )$$

In the examples illustrated in FIGS. 5A and 5B, the transient response calculator 210 uses the divider 513 to discretize the result (ct) of the division by the divider 512 with the sampling frequency fs. Specifically, the transient response calculator 210 may calculate the estimated supply voltage (vdm) according to the following Equation (2), for example.

$$vdm = vdm \cdot {z}^{- 1} + \frac{ct}{Cn \cdot fs} \\ ct = cs - ( ca + ng 1 \cdot vde ) \qquad ( 2 )$$

As illustrated in FIGS. 5A and 5B, the estimated current value calculator 240 includes a calculator 521, an adder 522, and a delay unit 523, for example. The calculator 521 calculates a value of (dv/Ln/fs), where dv represents a voltage applied between both ends of a power source filter, Ln represents inductance (for example, an inductor 814 illustrated in FIGS. 8A and 8B) of the LC circuit included in the power supply 230, and fs represents the sampling frequency. The calculator 521 outputs the result (ds) of the calculation to the adder 522.

The adder 522 adds the calculation result output from the calculator 521 to a signal output from the delay unit 523. Thus, the adder 522 may calculate an estimated current value (supply current*). The adder 522 outputs the result of the addition to the delay unit 523 and the transient response calculator 210. The delay unit 515 delays the addition result output from the adder 514 for a predetermined time and outputs the addition result to the adder 514.

Specifically, the estimated current value calculator 240 may calculate the estimated current value (supply current*=cs) according to the following Equation (3), for example.

$$cs = \int \frac{dv}{Ln} \cdot dt \qquad ( 3 )$$

In the examples illustrated in FIGS. 5A and 5B, the estimated current value calculator 240 uses the calculator 521 to discretize a value of (dv/Ln) with the sampling frequency fs. Specifically, the estimated current value calculator 240 may calculate the estimated current value (supply current*=cs) according to the following Equation (4).

$$cs = cs \cdot {z}^{- 1} + \frac{dv}{Lv \cdot fs} \qquad ( 4 )$$

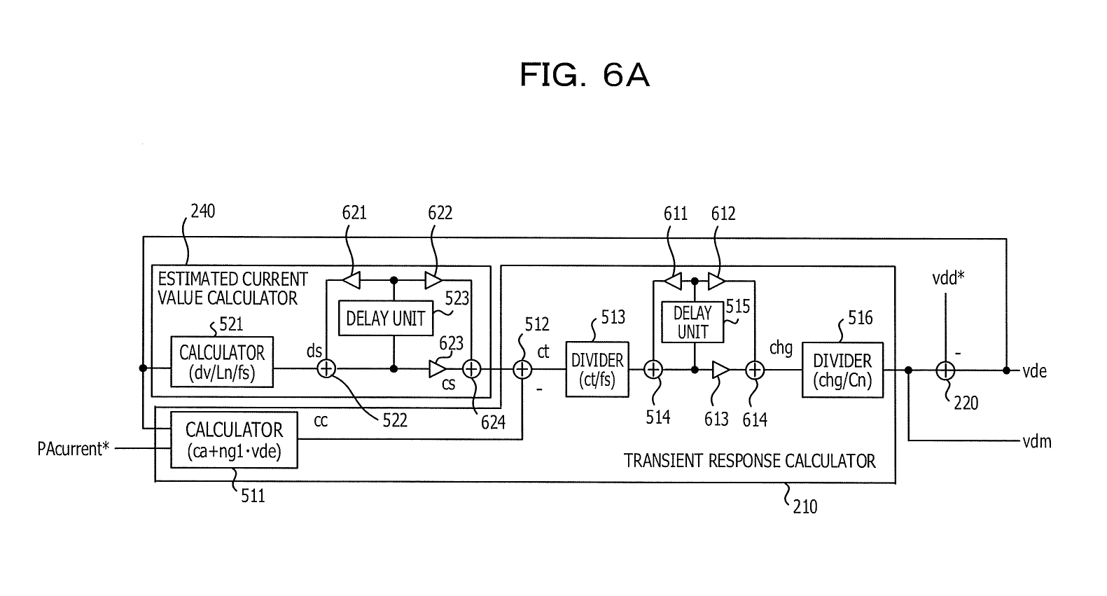

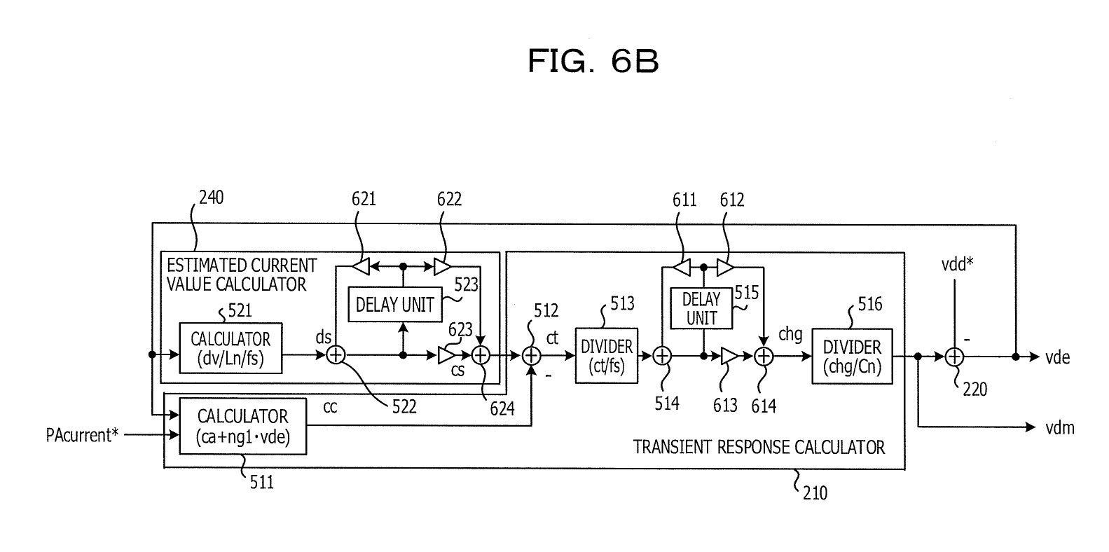

FIG. 6A is a diagram illustrating a second example of the configuration of the transient response calculator and the configuration of the estimated current value calculator. FIG. 6B is a diagram illustrating an example of the flows of signals in the second example, illustrated in FIG. 6A, of the configuration of the transient response calculator and the configuration of the estimated current value calculator. Parts that are illustrated in FIGS. 6A and 6B and are the same as those illustrated in FIGS. 5A and 5B are represented by the same reference numerals as those illustrated in FIGS. 5A and 5B, and a description thereof is omitted.

As illustrated in FIGS. 6A and 6B, the transient response calculator 210 has the configuration illustrated in FIGS. 5A and 5B and may include amplifiers 611 to 613 and an adder 614. The adders 514 and 614, the delay unit 515, and the amplifiers 611 to 613 form a digital filter with a nonlinear gain.

The adder 514 adds the division result output from the divider 513 to a signal output from the amplifier 611. The adder 514 outputs a result of the addition to the delay unit 515 and the amplifier 613. The delay unit 515 delays the addition result output from the adder 514 for a predetermined time and outputs the addition result to the amplifiers 611 and 612.

The amplifier 611 outputs the addition result output from the delay unit 515 to the adder 514. The amplifier 612 outputs the addition result output from the delay unit 515 to the adder 614. The amplifier 613 outputs the addition result output from the delay unit 515 to the adder 614. The amplifier 613 outputs the addition result output from the adder 514 to the adder 614.

The adder 614 adds the addition result output from the amplifier 612 to the addition result output from the amplifier 613. The adder 614 a result (chg) of the addition to the divider 516. The transient response calculator 210 that has the configuration illustrated in FIGS. 6A and 6B may calculate the estimated supply voltage value (vdm) with higher accuracy.

As illustrated in FIGS. 6A and 6B, the estimated current value calculator 240 has the configuration illustrated in FIGS. 5A and 5B and may include amplifiers 621 to 623 and an adder 624. The adder 522 adds the calculation result output from the calculator 521 to a signal output from the amplifier 621. The adder 522 outputs a result of the addition to the delay unit 523 and the amplifier 623. The delay unit 523 delays the addition result output from the adder 522 for a predetermined time and outputs the addition result to the amplifiers 621 and 622.

The amplifier 621 outputs, to the adder 522, the addition result output from the delay unit 523. The amplifier 622 outputs, to the adder 624, the addition result output from the delay unit 523. The amplifier 623 outputs, to the adder 624, the addition result output from the adder 522.

The adder 624 adds the addition result output from the amplifier 622 to the addition result output from the amplifier 623. The adder 624 outputs a result (cs) of the addition to the subtractor 512. The estimated current value calculator 240 that has the configuration illustrated in FIGS. 6A and 6B may calculate the estimated current value (supply current*=cs) with higher accuracy.

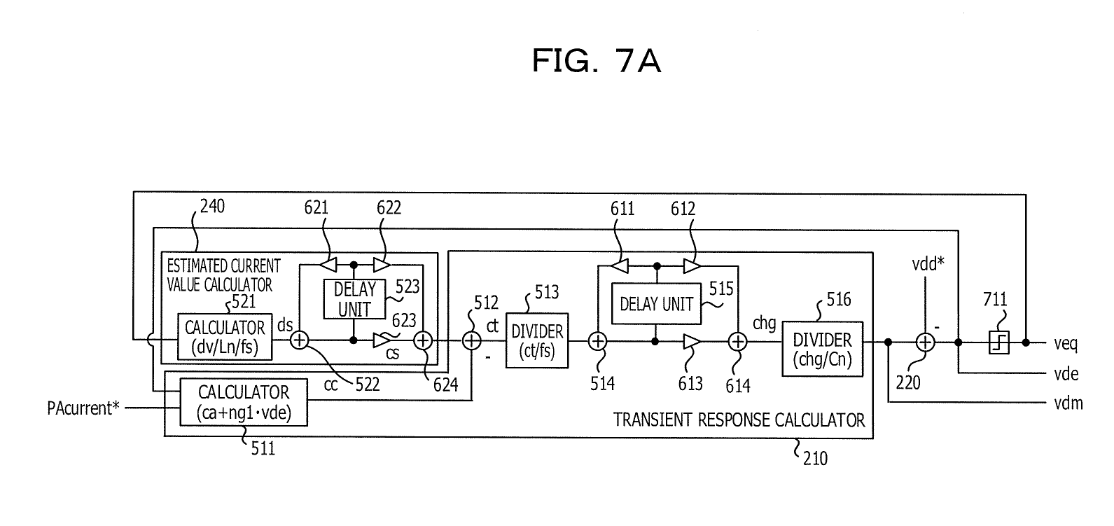

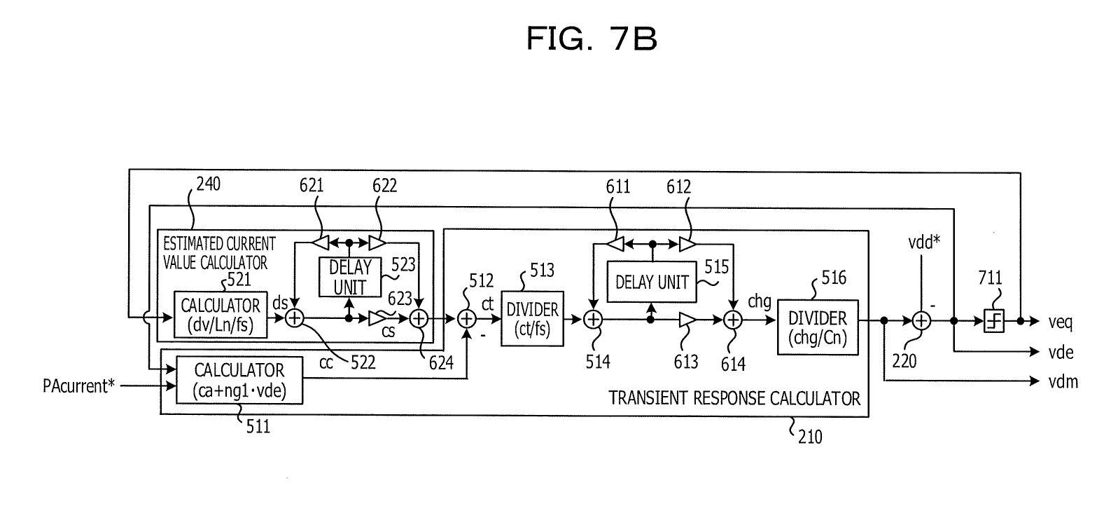

FIG. 7A is a diagram illustrating a third example of the configuration of the transient response calculator and the configuration of the estimated current value calculator. FIG. 7B is a diagram illustrating an example of the flows of signals in the third example, illustrated in FIG. 7A, of the configuration of the transient response calculator and the configuration of the estimated current value calculator. Parts that are illustrated in FIGS. 7A and 7B and are the same as those illustrated in FIGS. 6A and 6B are represented by the same reference numerals as those illustrated in FIGS. 6A and 6B, and a description thereof is omitted.

As illustrated in FIGS. 7A and 7B, the amplifying device 200 has the configuration illustrated in FIGS. 6A and 6B and may include a quantizer 711. The quantizer 711 corresponds to the pulse generator 320 illustrated in FIGS. 3A and 3B, for example. The quantizer 711 quantizes the differentiated signal output from the subtractor 220. Then, the quantizer 711 outputs the quantized differentiated signal (veq) to the estimated current value calculator 240 and the power supply 230 (refer, for example, to FIGS. 8A and 8B). The calculator 521 of the estimated current value calculator 240 uses the differentiated signal output from the quantizer 711 to calculate the value of (dv/Ln/fs).

Since the amplifying device 200 has the configuration illustrated in FIGS. 7A and 7B, an effect of a ripple generated in a power control element may be reduced.

### Example of Configurations of Power Supply and Modulator

FIG. 8A is a diagram illustrating an example of a configuration of the power supply and a configuration of the modulator. FIG. 8B is a diagram illustrating an example of the flows of signals in the example, illustrated in FIG. 8A, of the configuration of the power supply and the configuration of the modulator. As illustrated in FIGS. 8A and 8B, the power supply 230 includes an amplifier 811, a transistor 812, a diode 813, an inductor 814, and a capacitor 815, for example.

A signal (veq) to control the power supply 230 is input to the amplifier 811. The signal to control the power supply 230 is the pulse signal output from the pulse generator 320 illustrated in FIGS. 3A and 3B, for example. The signal to control the power supply 230 may be the differentiated signal output from the quantizer 711 illustrated in FIGS. 7A and 7B. The amplifier 811 amplifies the input control signal and outputs the amplified control signal to the transistor 812.

The transistor 812 is a field effect transistor (FET), for example. The control signal output from the amplifier 811 is input to a gate of the transistor 812. The power (Vsup) is input to a drain of the transistor 812. A source of the transistor 812 is connected to the diode 813 and the inductor 814.

One of ends of the diode 813 is connected to the transistor 812 and the inductor 814, while the other end of the diode 813 is grounded. One of ends of the inductor 814 is connected to the transistor 812 and the diode 813, while the other end of the inductor 814 is connected to the capacitor 815 and the power terminal of the power amplifier 260. One of ends of the capacitor 815 is connected to the inductor 814 and the power terminal of the power amplifier 260, while the other end of the capacitor 815 is grounded.

As illustrated in FIGS. 8A and 8B, the modulator 330 includes multipliers 821 and 822, for example. The I and Q channel signals (compensated signals) to be transmitted are input to the multipliers 821 and 822, respectively. The I and Q channel signals to be transmitted are the signals output from the delay adjusters 461 and 462 illustrated in FIGS. 4A and 4B, for example.

The multiplier 821 modulates the input I channel signal by multiplying the I channel signal by a clock signal. The multiplier 822 modulates the input Q channel signal by multiplying the Q channel signal by the clock signal. The modulator 330 synthesizes results of the multiplication by the multipliers 821 and 822 with each other and outputs, as a signal to be transmitted, a signal obtained by synthesizing the multiplication results with each other to the power amplifier 260.

Control Signal and Waveform of Supplied Voltage

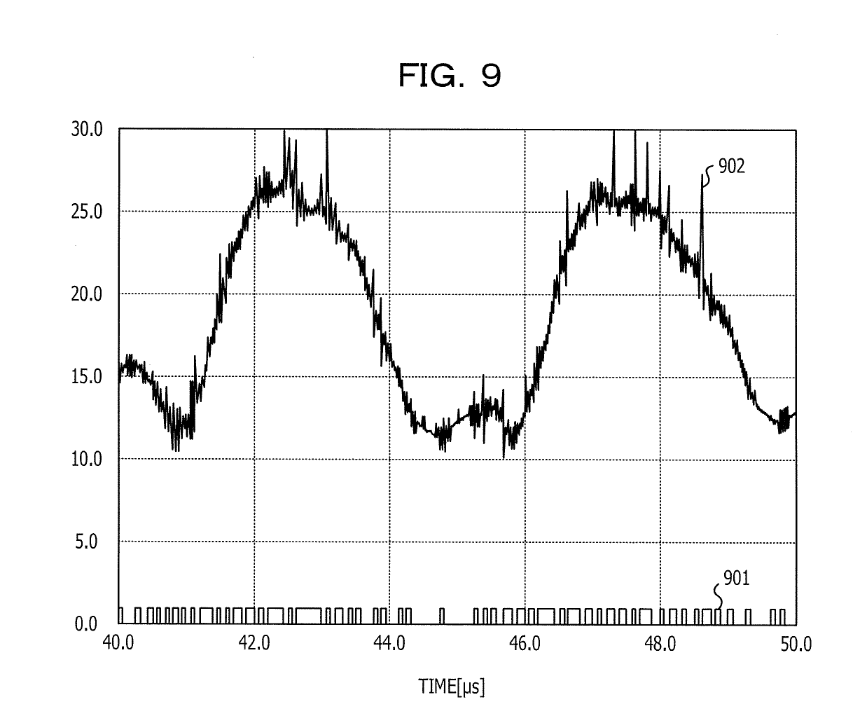

FIG. 9 is a diagram illustrating an example of the control signal and the waveform of the voltage supplied. In FIG. 9, the abscissa represents time (μs), and the ordinate represents the voltage to be supplied. A control signal 901 represents the control signal (veq) to be input to the power supply 230, while a voltage 902 represents the voltage to be supplied from the power supply 230 to the power amplifier 260.

Improvement of Signal Output from Power Amplifier

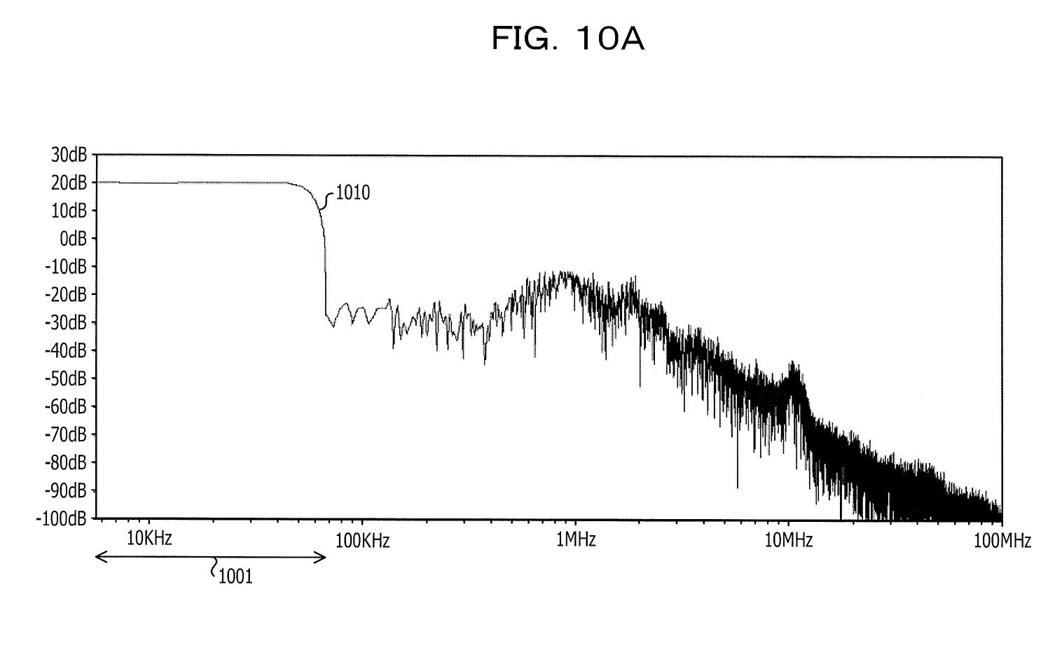

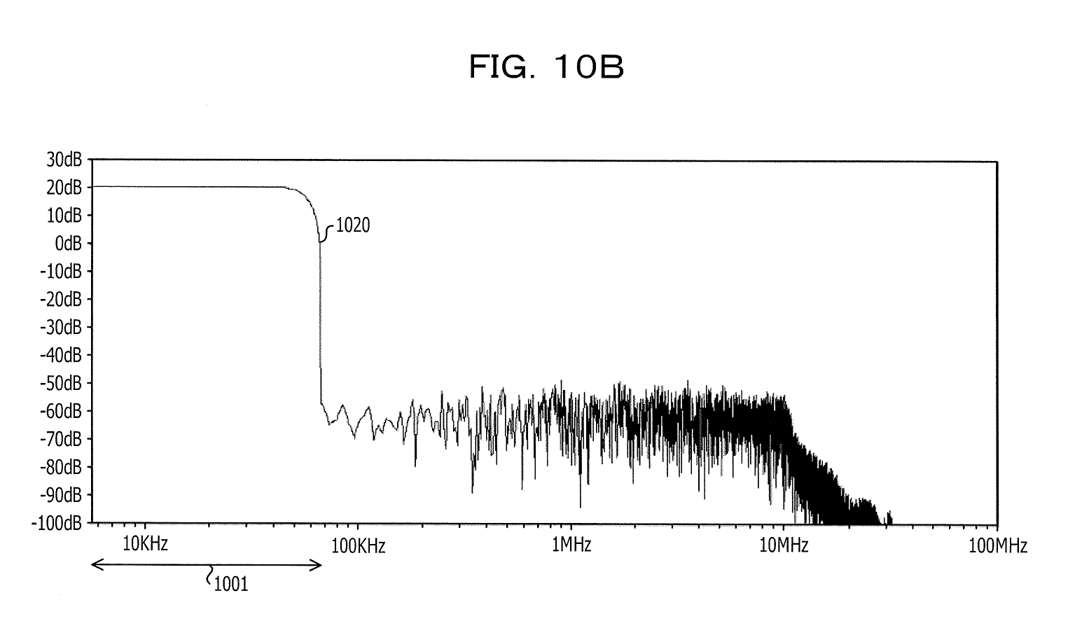

FIG. 10A is a diagram illustrating an output spectrum of the power amplifier when the voltage supply control is stopped as a reference. FIG. 10B is a diagram illustrating an output spectrum of the power amplifier when the voltage supply control is executed. In each of FIGS. 10A and 10B, the abscissa represents a frequency and the ordinate represents strength. In each of FIGS. 10A and 10B, a signal band 1001 is a band of a signal to be amplified by the power amplifier 260 and to be transmitted.

A spectrum 1010 illustrated in FIG. 10A represents the spectrum of the signal output from the power amplifier 260 when the voltage supply control according to the second embodiment is stopped. A spectrum 1020 illustrated in FIG. 10B represents the spectrum of the signal output from the power amplifier 260 when the voltage supply control according to the second embodiment is executed.

As represented by the spectrums 1010 and 1020, a noise band that is higher than the signal band 1001 is suppressed by executing the voltage supply control according to the second embodiment, and the quality of the signal output from the power amplifier 260 and to be transmitted may be improved.

As described above, according to the distortion compensating apparatus and the distortion compensation method, the amplification efficiency may be improved.

For example, the efficiency of amplifying a broadband signal to be transmitted by a transmitter may be improved by dynamically estimating a power source variation by model calculation of the transient response of the power source circuit and using the result of the estimation for the high-speed control of the supply voltage. In addition, a distortion, caused by the power source variation, of the signal to be output from the amplifier may be compensated for using the power source variation estimated.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A distortion compensating apparatus comprising:
a memory; and
a processor coupled to the memory and configured to:
calculate a transient response of a power source circuit, in accordance with an estimated value of a current to be consumed by an amplifier based on a signal to be amplified by the amplifier, and in accordance with an objective supply voltage, based on the signal, of a voltage to be supplied to the amplifier from the power source circuit, and
correct the signal to be input to the amplifier based on a difference caused by the transient response from the objective supply voltage.

2. The distortion compensating apparatus according to claim 1,
wherein the processor is configured to control the power source circuit by the difference.

3. The distortion compensating apparatus according to claim 1,
wherein the processor is configured to compensate for current deviation of the current, caused by the difference.

4. The distortion compensating apparatus according to claim 1,
wherein the processor is configured to calculate the transient response based on an estimated value, based on the difference, of a current flowing in the power source circuit.

5. The distortion compensating apparatus according to claim 4,
wherein the processor is configured to quantize a differentiated signal that represents the difference, and
wherein the processor is configured to calculate the estimated value of the current flowing in the power source circuit based on the differentiated signal quantized.

6. The distortion compensating apparatus according to claim 5,
wherein the processor is configured to input the differentiated signal quantized to the power source circuit configured to control the voltage based on the inputted differentiated signal quantized.

7. The distortion compensating apparatus according to claim 1,
wherein the processor is configured to calculate the transient response using a digital filter with a nonlinear gain.

8. The distortion compensating apparatus according to claim 1,
wherein the processor is configured to correct the signal corrected based on information of an association of the signal with a correction value of an amplitude and a correction value of a phase.

9. The distortion compensating apparatus according to claim 1,
wherein the processor is configured to obtain the objective supply voltage based on information of an association of the signal with the objective supply voltage.

10. The distortion compensating apparatus according to claim 1,
wherein the processor is configured to obtain the estimated value based on information of an association of the signal with the estimated value.

11. The distortion compensating apparatus according to claim 1,
wherein the processor is configured to adjust a delay difference between the signal to be input to the amplifier and the voltage to be supplied from the power source circuit to the amplifier.

12. A distortion compensation method comprising:
calculating, using a processor, a transient response of a power source circuit, in accordance with an estimated value of a current to be consumed by an amplifier based on a signal to be amplified by the amplifier, and in accordance with an objective supply voltage, based on the signal, of a voltage to be supplied to the amplifier from the power source circuit; and
correcting the signal to be input to the amplifier based on a difference caused by the transient response from the objective supply voltage.

13. An amplification apparatus comprising:
an amplifier configured to amplify a signal;
a power source circuit configured to supply a voltage to the amplifier; and
a processor configured to:
calculate a transient response of the power source circuit, in accordance with an estimated value of a current to be consumed by the amplifier based on the signal, and in accordance with an objective supply voltage of the voltage based on the signal; and
correct the signal to be input to the amplifier based on a difference caused by the transient response from the objective supply voltage.
